(19) United States
(12) Patent Application Publication
(10) Pub. No.: US 2012/0103399 A1
(43) Pub. Date: May 3, 2012

(54) PHOTOVOLTAIC MODULE AND PHOTOVOLTAIC DEVICE

(76) Inventor: Thomas Lauinger, Niederberg (DE)

(21) Appl. No.: 13/381,218

(22) PCT Filed: Jul. 1, 2010
(86) PCT No.: PCT/EP10/59407

§ 371 Date: Dec. 28, 2011

(30) Foreign Application Priority Data
Jul. 6, 2009 (DE) 10 5009 031 982.4

(51) Int. Cl. H01L 31/048

(52) U.S. Cl. 136/251

(57) ABSTRACT

The invention relates to a photovoltaic module (PVM) for installation in a photovoltaic device, wherein the photovoltaic module (PVM) comprises an arrangement of a plurality of solar cell strings (ST), each made of a number of solar cells connected in series, and wherein the arrangement of the solar cell string (ST) is received in an enclosure (E) formed of a plurality of module part (FRM, GLP, BP), and wherein the module parts (FRM, GLP, BP) are designed in an electrically conductive manner and are interconnected, so that the enclosure (E) implements an electrostatically effective casing of the at least one solar cell string (ST). In order to prevent high field intensities in the interior of the enclosure (E), the enclosure (E) has at least one contact element (R; EMB) for connecting the potential (PA; PA′) of the electrostatically effective casing to at least one defined electrical potential.

The invention relates to a photovoltaic module according to the preamble of claim 1 and to a photovoltaic device comprising a plurality of such photovoltaic modules according to the preamble of the alternative independent claim. In particular, the invention relates to a photovoltaic module for installation in and construction of photovoltaic devices which are suitable as a source of power supply to consumers by way of a high voltage-direct current transmission pathway, wherein the consumers can be located far from or close to the particular photovoltaic device.

Photovoltaic devices and systems are used to an increasing extent in so-called photovoltaic power plants which are installed primarily in sunny regions and are intended to generate power in a centralized manner for the available, consumer-side power supply networks which are often located a great distance away. Such photovoltaic devices preferably cover a large area and are installed in desert regions, for instance, in order to make a decisive contribution to power generation from solar energy. These systems are also referred to as “Very Large Scale Photovoltaic Systems”, i.e. VLS-PV systems, and are presented in the article “Very Large Scale PV-Systems” by Dr. Rudolf Minder in the publication “FVS-Themen 2002” on pages 67 to 70, for example (published by the Forschungsverbund Sonnenenergie, Berlin, Germany, available on the internet at the URL: www.fv-sonnenenergie.de). It describes a modular design of a plurality of PV modules, which is not described in greater detail herein. Various transport techniques are proposed for transmitting the electricity that is obtained, such as high voltage-direct-current transmission, i.e. HGÜ.

Photovoltaic modules are described in DE 39 35 826 A1, U.S. Pat. No. 5,542,988 A and US 2006/0196 535 A1.

A power supply which functions particularly efficiently by way of a photovoltaic device or system comprising photovoltaic modules is provided in the previous application DE 10 2009 004 679. In that case, a plurality of photovoltaic modules (PV modules) for generating direct voltage are interconnected in a parallel and/or series circuit, and so the direct voltage which is generated is suitable for high voltage-direct current transmission (HGÜ). Every PV module comprises a plurality of module parts which form an enclosure for the plurality of solar cell strings. The module parts include a frame, a front glass pane and a back panel. Approximately 70-120 volts can be generated in a single module simply by interconnecting a plurality of solar cell strings. By subsequently interconnecting a plurality of PV modules to form blocks and strings, it is possible to generate direct voltages in the high voltage range of several thousand volts and more. It is therefore possible to generate a sufficiently high direct voltage even at the generator side, i.e. at the site of the photovoltaic device, which can then be delivered to the HGÜ pathway and transmitted to the consumer side. At the end of the HGÜ pathway it is only necessary to convert the transmitted direct voltage into a desired alternating voltage. Due to the interconnection of PV modules, the direct voltage generated by the photovoltaic device can greatly exceed the dielectric strength, which is currently a maximum of approximately 1 kV, and can be in a high voltage range of 1 kV to 2 MV.

The direct voltages generated using the technique proposed therein quickly exceed the typical dielectric strengths of approximately 1 kV. This is possible in the case of an insulated support of PV modules or PV blocks in particular because arcs are thereby prevented from forming between the embedded solar cell strings and the enclosure or module encapsulation (made of front glass pane, rear film or rear glass pane and frame). Measures should therefore be taken to prevent field effects from occurring due to the high voltage potentials, which can have negative effects on the function of the solar cells and possibly even damage the encapsulation material or lead to corona discharges and, therefore, non-negligible power losses. It is therefore desirable to create a modular design which permits the series connection of a large number of modules without a problem arising due to the occurrence of very high voltage potentials. The new design should also be particularly well suited for an interconnection of a plurality of PV modules to form blocks and/or strings.

The problem addressed by the present invention is therefore that of improving a photovoltaic module of the initially stated type such that the stated disadvantages are overcome. In particular, the improved photovoltaic module should be suitable for use in long series connections having string voltages in the range of 2 kV to 2 MV. In addition, a photovoltaic device should be provided, which is suited, in particular, for delivering the generated voltage directly into a HGÜ pathway.

The above-mentioned problem is solved by a photovoltaic module having the features of claim 1, and by a photovoltaic device having the features of the alternative independent claim.

According thereto, the module parts are electrically conductive and interconnected, and so the enclosure forms an electrostatically effective covering of the at least one solar cell string, and the enclosure is equipped with at least one contact element for connecting the potential of the electrostatically effective covering to at least one defined electrical potential.

The enclosure is therefore in the form of an electrostatically effective covering and is equipped with at least one contacting means. It is therefore possible to connect the covering to a defined electrical potential, e.g. to the potential of a connection point of the solar cell string, i.e. approximately to the potential at the beginning, the end, or in the center of the series connection of solar cells. This can be achieved by way of a highly resistive, discrete resistor, for example. The at least one contacting means can also be achieved by way of a highly resistive embedding or filler material which fills the interior of the enclosure and therefore embeds the solar cells or the string in a highly resistive manner and establishes contact with the conductive enclosure. These and similar embodiments of contact elements result in a defined potential connection of the enclosure and, in particular, a highly resistive potential equalization between solar cell strings and the enclosure.

In a preferred embodiment of the invention, the at least one contact element is in the form of an at least highly-resistive conductive contact point disposed on one of the module parts. By way of this contact point or connection point, which is accessible from the outside, the enclosure can be connected to a desired potential (e.g. the center potential of a module group, having a maximum voltage difference of +/−1000 volts from the potential of the solar cell string in the interior of the module) by way of a conductive element.

Preferably the at least one contact element is in the form of a highly-resistive conductive element and/or is made of a highly-resistive conductive material. As a result, the potential connection is highly resistive (in the mega-ohm or giga-ohm range, or higher) several and very low potential equalization currents (in the micro-ampere range or lower) can flow.

For example, the at least one contact element is in the form of a highly-resistive conductive resistor. It can be a discrete component disposed between a contact point on the solar cell string and the enclosure, in particular the frame.

As a contacting means and for potential equalization, the highly-resistive conductive material can be in the form of an embedding material inserted into the enclosure, wherein the at least one solar cell string is accommodated within the enclosure in the embedding material. The at least one contact element is therefore in the form of a highly-resistive conductive embedding material which is inserted into the interior of the enclosure and establishes potential equalization between the solar cell string and the enclosure (frame, front side and rear side). For example, the embedding material can be formed by two films which are inserted before assembly of the module, which are caused to melt and/or foam and thereby embed the solar cell string.

The enclosure is preferably designed such that one of the module parts can be the frame itself, which is made of a conductive material, in particular metal, and/or is equipped with at least one element which is electrically conductive. Another module part can be the rear panel which is made of a conductive material and/or is equipped with at least one element which is electrically conductive. Furthermore, a glass pane can be used, which is made of a conductive material and/or is equipped with at least one element which is electrically conductive.

Overall, an electrically at least highly-resistive conductive enclosure results for each PV module, which encloses the at least one solar cell string and can be connected to the approximately same electrical potential of the solar cell string, thereby ensuring that high field strengths can no longer occur in the interior of the module. The electrical potential of the solar cell string can have a maximum difference which corresponds to the dielectric strength of the module, which is typically approximately 1 kilovolt. To design the enclosure as an electrostatically effective covering, the highly resistive conductivity can also be achieved by way of a coating or vaporization, in particular in the case of the glass pane, although it is not necessary to design all regions of the glass pane to be conductive. It can be sufficient to vapor-deposit a lattice or a linear structure comprising conductive coating lines. The coating can be applied on the inner or outer surface of the glass. The glass material itself can also be equipped with conductive elements and particles.

The electrical contacting means of the enclosure can also be achieved by the use of an electrically conductive frame which can be contacted to an electrically conductive support using screws, for example. Alternatively, electric cable connection points can be provided on the frame or on the module back side.

These and further advantages also result from the dependent claims.

To prevent corona discharges it is therefore advantageous for the frame of the photovoltaic module to have a rounded shape. It is preferably asymmetrical with respect to the photovoltaic module, and, in particular, is designed such that the centroid and/or center of the frame is located outside, i.e. in front of or behind the module plane. Shadows are therefore prevented from forming on the module surface.

A preferred embodiment can be achieved by accommodating the at least one solar cell string inside the enclosure in a highly-resistive conductive embedding material. As a result, highly resistive (and, therefore, loss-free) potential equalization always takes place between solar cell string(s) and the enclosure, which ensures that the frame of the particular PV module assumes the potential of the solar cell string. This is necessary if the enclosure cannot be connected externally to an electrically conductive support at a defined electrical potential by way of an electrically conductive contact because an electrically insulating support is used, for example, such as one made of wood.

Alternatively, it can also be achieved by electrically connecting the at least one solar cell string by way of a highly-resistive discrete resistor to the enclosure, in particular to the frame.

The invention and the resulting advantages are described in greater detail in the following with reference to embodiments and the attached drawings, which show:

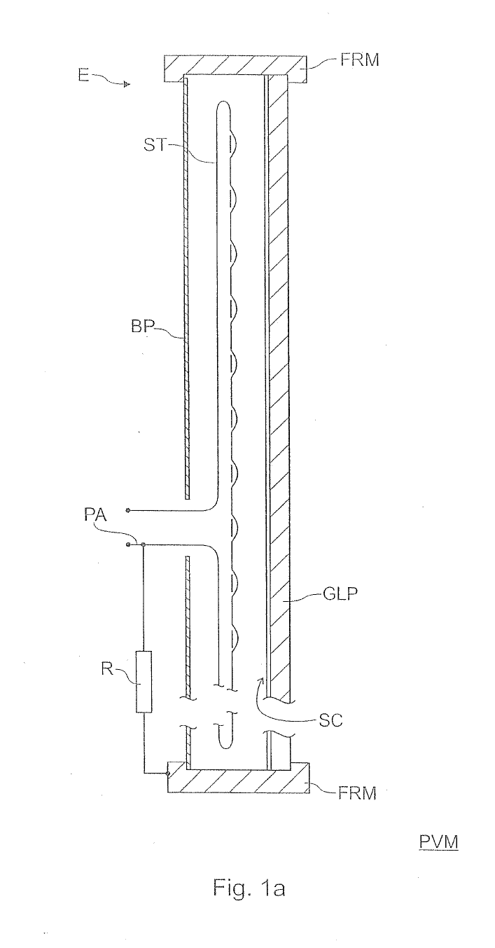

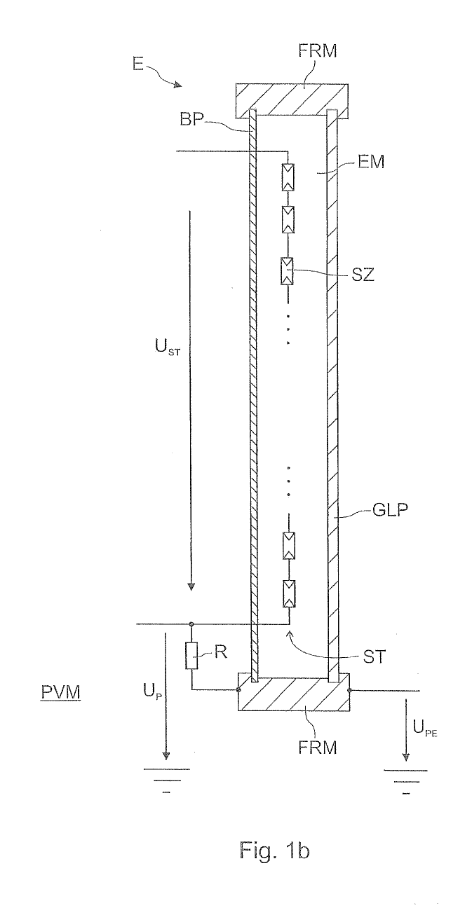

FIG. 1a the design of a first photovoltaic module (PV module), in a schematic cross-sectional view;

FIG. 1b the PV module according to FIG. 1a, wherein the at least one solar cell string is depicted in the form of an equivalent circuit diagram;

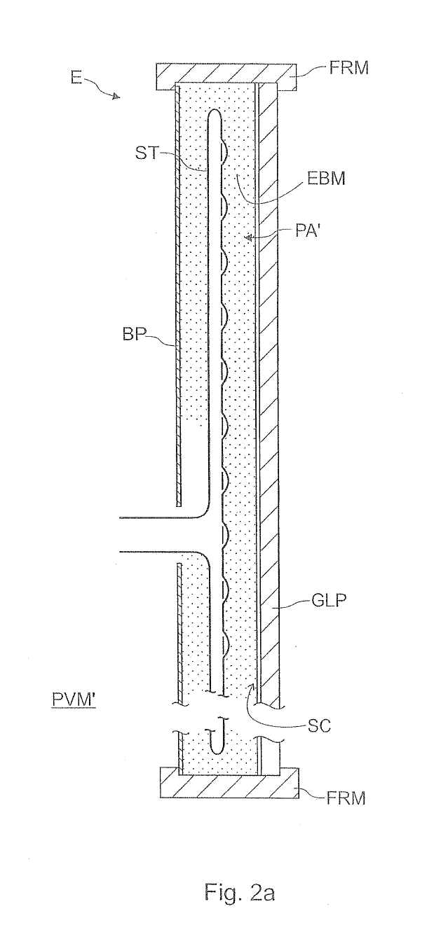

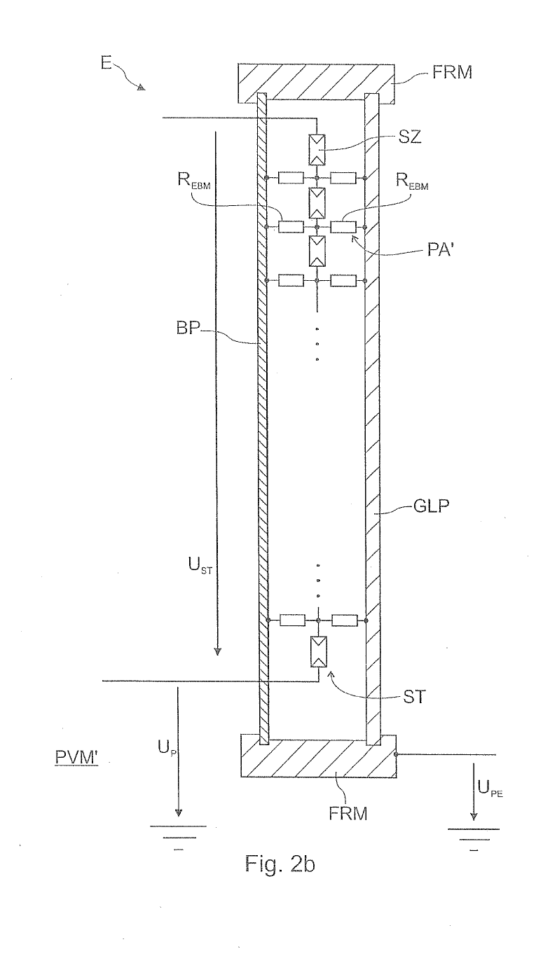

FIG. 2a the design of a second photovoltaic module (PV module), in a schematic cross-sectional view;

FIG. 2b the PV module according to FIG. 2a, wherein the at least one solar cell string and the highly resistive elements are depicted in the form of an equivalent circuit diagram;

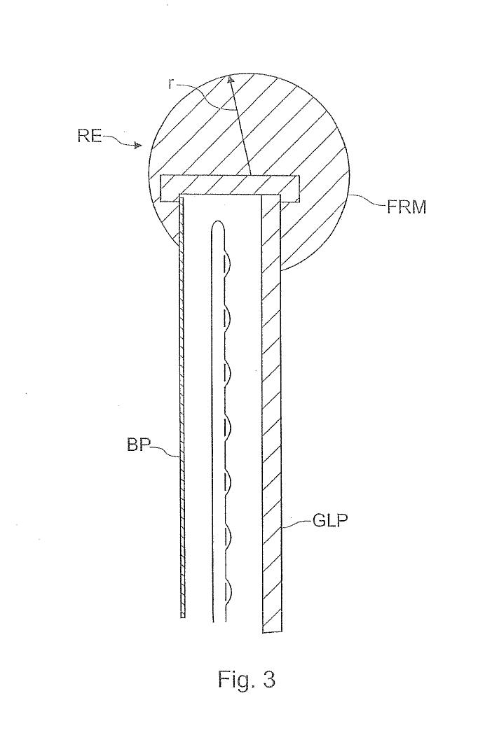

FIG. 3 the designs of the PV module frame according to the invention, in a partial view; and

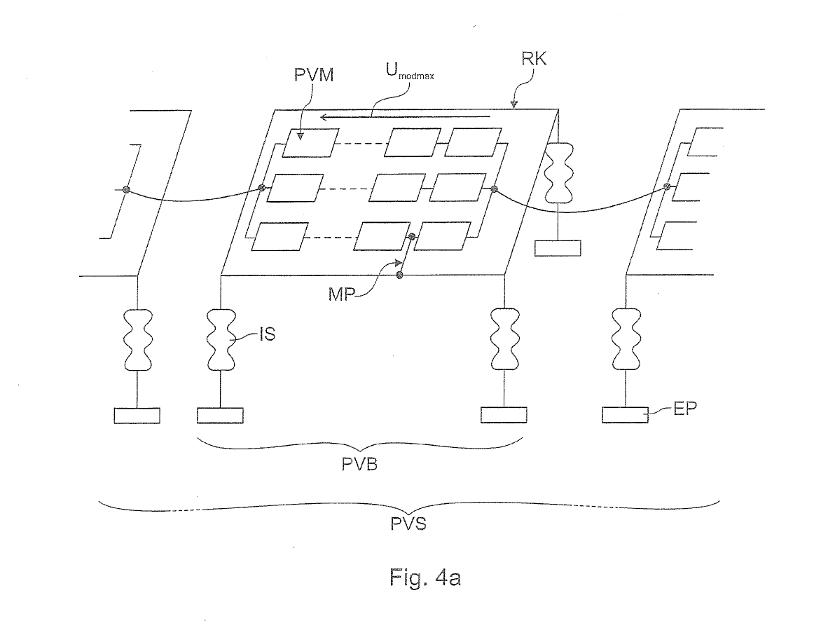

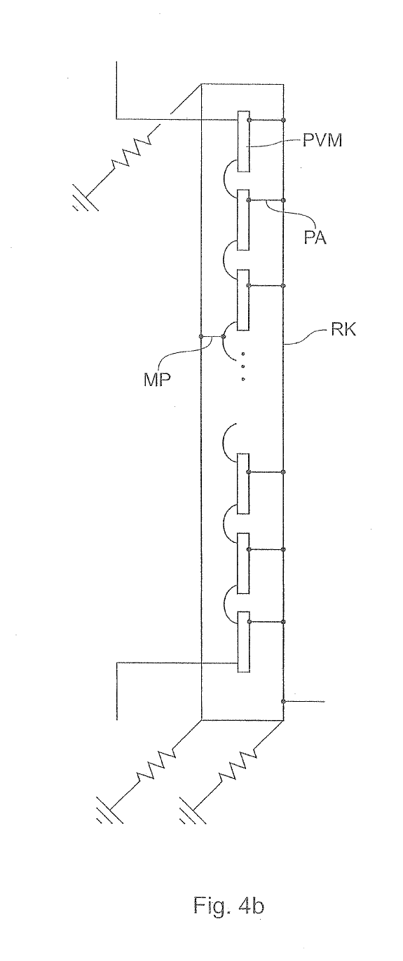

FIG. 4a,b the schematic design of a PV string formed of a plurality of PV modules, as part of a PV device.

FIG. 1a shows, in a cross-sectional view, the design of a photovoltaic module (PV module) according to the invention, in a first embodiment, wherein the PVM module is oriented vertically in the depiction. In the installed position, the module would be oriented at a slant, thereby ensuring that the front side or the top side (the right side in this case) of the module is oriented as perpendicular as possible with respect to the solar radiation. The PVM module mainly comprises one or more solar cell strings ST which are disposed in the interior of the module and only one string of which is shown here, as an example. In addition, a glass pane GLP is located on the top side or front side of the PVM module, and a back panel BP is located on the underside or back side (the left side in this case), which is made of metal, for instance, in this case, but which can also be a rear film or a glass pane, for example. The system which is described is enclosed by a frame FRM which is also made of metal in this case. The frame, the glass pane, and the rear side are module parts which form an enclosure or encapsulation for the at least one solar cell string ST.

If a plurality of modules is now connected in series in order to increase the voltage generated, and the modules are supported in an insulated manner (see also FIGS. 4a,b) to permit the typical dielectric strength of the module to be exceeded, then very high field strengths can also occur at the strings ST relative to the surroundings. As a result, the solar cell function may become impaired and the embedding material may even become damaged.

To prevent this, the enclosure shown in FIG. 1a, which comprises a frame FRM, a glass pane GLP and a back panel BP, is designed to be electrically conductive and at least highly-resistive conductive, thereby permitting the entire enclosure to be connected to a definable potential. At least one contact element is provided for this purpose. This can be achieved, for example, by way of a further highly resistive element, such as the resistor R of 5 GΩ, for example, as shown here, which connects the inner string ST to the enclosure and therefore equalizes the potential. It is sufficient for the resistor R to connect, in a highly-resistive conductive manner, one point of the string ST, e.g. one of the connectors, to a module part of the enclosure, such as the frame FRM.

FIG. 1b shows a circuit diagram equivalent to that shown in FIG. 1a. The solar cell string ST comprises a plurality of series-connected solar cells SZ which, in all, generate a string voltage U_{ST}. By connecting a plurality of modules in series and supporting the modules in an insulated manner, a very high potential difference Up of several kilovolts or even megavolts can result between one string ST and the surroundings (ground potential). Voltages which can greatly exceed the dielectric strength of a single module are therefore generated and, therefore, high field strengths occur, for which conventional modules according to the prior art are not designed.

Due to a discrete resistor R provided on each module, potential is equalized between the particular string ST and the particular enclosure or the frame FRM, thereby ensuring that the potential Up between the string beginning and the ground is equivalent to the potential between the enclosure and ground. In other words: The enclosure is at the potential of the beginning of the string, and so, at most, the string voltage Ust can occur between the enclosure and the solar cells of the string.

An alternative design is shown in FIGS. 2a and 2b. In that case, a highly-resistive conductive embedding material EBM is filled into the enclosure or the interior of the module PVM′, which equalizes potential between the string ST and the enclosure comprising the frame FMR, the glass pane GLP and the back panel BP. The equivalent circuit diagram shown in FIG. 2b depicts corresponding highly resistive resistors R_{EBM}, each of which connects one solar cell SZ to the back panel BP or the glass pane GLP. A highly-resistive conductive transparent plastic can be used as the embedding material EBM, for example.

In the embodiments depicted in FIGS. 2a and 2b, potential is equalized between the inner solar cell string ST and the enclosure, thereby ensuring that the enclosure and, therefore, the frame FRM have a potential which lies at the center potential of the string ST. Due to the highly resistive materials having very high surface resistances (e.g. R′=approximately 10E13 Ωcm² with Rges=R′/module surface), only very weak equalization currents flow, thereby ensuring that none of the components or even the entire construction is at risk of damage.

In addition to the above-described measures, the frame of the module itself can be designed as shown in FIG. 3, to prevent corona discharges in particular. To this end, the frame FRM′ is provided with a shape having no sharp points or edges, if possible. The rounded shape shown in FIG. 3 corresponds to a circular or spherical shape of the frame FRM′. Preferably, circular radii of at least r=3 cm should be achieved. The necessary minimum radius is dependent upon the maximum voltage applied to the module. Similar designs, such as a polygon having several lateral surfaces, which is similar to the shape of a circle or a sphere, are also possible. The frame FRM′ shown in FIG. 3 has no edges or sharp corners, if possible, but rather has a shape which is round or rounded (i.e. without edges). Preferably, circular radii of at least r=3 cm should be achieved. The roundings are preferably asymmetrical with respect to the photovoltaic module PVM, thereby ensuring that the centroid or center of the frame FRM′ is located behind the module plane, for example. Shadows are thereby prevented from forming on the module surface (front side).

The layout of a photovoltaic device or system, in which modules are supported in an insulated manner, is illustrated in FIGS. 4a and 4b. The device comprises at least one PV string PVS formed of a plurality of PV modules PVM, which is depicted in greater detail in the figure. As shown, a system of a plurality of PV modules PVM in the form of module blocks PVB is provided for each string PVS, each of which is mounted on a frame construction RK which is insulated with respect to ground and is supported. Due to the insulation, the PV modules PVM can be raised to a very high electrical potential. Ceramic or plastic insulators IS, for example, are used for insulation.

Finally, the PV system or device (not depicted) is formed by connecting a plurality of such PV strings.

To now connect the enclosures of modules mounted on a PVP provided herein to potential which corresponds approximately to the potential of the solar cell strings, the above-described contact elements (resistor, embedding) can be used and/or an electrically conductive contact having an electrically conductive frame construction RK of the support can be created by way of potential connections PA (see FIG. 4b). The potential of the frame construction can be defined in that they are connected in an electrically conductive manner at a defined point, namely the potential connection MP, to a connection point of the solar cell strings (see FIGS. 4a,b). Therefore, field strengths which are harmful to solar cells or the embedding material cannot occur in the interior of the individual modules PVM.

As an alternative to an electrically conductive support, additional potential equalization cables can be installed, which connect the enclosures of the modules to the potential connection MP.

### LIST OF REFERENCE CHARACTERS

PVM Photovoltaic module (PV module) comprising:
ST Solar cell strings (only one is depicted, for example purposes)
FRM Frame for the lateral enclosure of the strings ST or for enclosing the PV module
GLP Glass pane (front-side enclosure of the string ST)
BP Back panel (back-side enclosure of the string ST)
R Highly-resistive conductive element in the form of a discrete resistor
EBM Embedding material, as a highly-resistive conductive element
SC Highly-resistive coating
RE Rounded shape of the module frame FRM
r Radius
PVB PV block (block composed of a plurality of PV modules)
PVS PV string (string composed of a plurality of PV blocks)
RK Frame construction for module block PVB
IS Insulators for the support
EP Ground potential
PA Potential connection by way of discrete contacting elements
PA′ Potential connection by way of embedding material
U_{ST} String voltage
U_{P} Voltage between solar cell string and ground potential
U_{PE} Voltage between enclosure and ground potential

1. A photovoltaic module (PVM) for installation in a photovoltaic device, wherein the photovoltaic module (PVM) comprises at least one solar cell string (ST), each of which is made of a number of solar cells connected in series, wherein the at least one solar cell string (ST) is accommodated in an enclosure (E) formed of a plurality of module parts (FRM, GLP, BP),
characterized in that
the module parts (FRM, GLP, BP) are electrically conductive and interconnected, and so the enclosure (E) forms an electrostatically effective covering of the at least one solar cell string (ST), and the enclosure (E) is equipped with at least one contact element (R; EBM) for connecting the potential (PA; PA′) of the electrostatically effective covering to at least one defined electrical potential.

2. The photovoltaic module (PVM) according to claim 1, characterized in that at least some of the module parts (FRM, GLP, BP) are electrically highly-resistive conductive.

3. The photovoltaic module (PVM) according to claim 1, characterized in that one of the module parts corresponds to a frame (FRM) made of a material, in particular metal, and/or equipped with at least one element which is electrically conductive.

4. The photovoltaic module (PVM) according to claim 1, characterized in that one of the module parts corresponds to a back panel (BP) made of a material and/or equipped with at least one element which is electrically conductive.

5. The photovoltaic module (PVM) according to claim 1, characterized in that one of the module parts corresponds to a glass pane (BP) admixed with a material and/or equipped with at least one element (SC) which is electrically conductive.

6. The photovoltaic module (PVM) according to claim 3, characterized in that the at least one electrically conductive element corresponds to a coating (SC) which is at least highly-resistive conductive.

7. The photovoltaic module (PVM) according to claim 6, characterized in that the coating (SC) is applied to one of the module parts (GLP; BP) in the form of strips or a lattice.

8. The photovoltaic module (PVM) according to claim 1, characterized in that the at least one contact element is in the form of an at least highly-resistive conductive contact point disposed on one of the module parts (FRM).

9. The photovoltaic module (PVM) according to claim 1, characterized in that the at least one contact element is in the form of a high-resistive conductive element (R) and/or is made of a highly-resistive conductive material (EBM).

10. The photovoltaic module (PVM) according to claim 9, characterized in that the at least one contact element is in the form of a highly-resistive conductive resistor (R).

11. The photovoltaic module (PVM) according to claim 10, characterized in that the at least one solar cell string (ST) is electrically connected by way of the highly-resistive conductive resistor (R) to the enclosure (E), in particular to the frame (FRM).

12. The photovoltaic module (PVM) according to claim 9, characterized in that the highly-resistive conductive material is in the form of an embedding material (E) inserted into the enclosure (E), wherein the at least one solar cell string (ST) is accommodated within the enclosure (E) in the embedding material (E).

13. The photovoltaic module (PVM) according to claim 3, characterized in that the frame (FRM′) of the photovoltaic module (PVM) has a rounded shape, in particular a circular or spherical shape.

14. The photovoltaic module (PVM) according to claim 13, characterized in that the rounded shape of the frame (FRM′) is asymmetrical to the photovoltaic module (PVM), in particular being designed such that the centroid and/or center of the frame (FRM′) is located outside of, or in front of or behind the module plane.

15. A photovoltaic device comprising a plurality of photovoltaic modules (PVM), wherein each photovoltaic module (PVM) comprises an arrangement of at least one solar cell string (ST), each of which is made of a number of solar cells (SZ) connected in series, wherein the at least one solar cell string (ST) is accommodated in an enclosure (E) formed of a plurality of module parts (FRM, GLP, BP),
characterized in that
the module parts (FRM, GLP, BP) are electrically conductive and interconnected, and so the enclosure (E) forms an electrostatically effective covering of the at least one solar cell string (ST), and the enclosure (E) is equipped with at least one contact element (R; EBM) for connecting the potential (PA; PA′) of the electrostatically effective covering to at least one defined electrical potential.

16. The photovoltaic device according to claim 15, characterized in that the plurality of photovoltaic modules (PVM) is mounted in a frame construction (RK) which is supported in an insulated manner in particular, wherein, in each case, the enclosure (E) of a photovoltaic module (PVM) has a potential connection (PA) by way of the at least one contact element to the frame construction (RK).

17. The photovoltaic device according to claim 15, characterized in that the frame construction (RK) is equipped with a potential connection (MP) which is connected at least to an enclosure (E) of the photovoltaic module (PVM).
